(19) United States
(12) Patent Application Publication
(10) Pub. No.: US 2008/0315141 A1
(43) Pub. Date: Dec. 25, 2008

(54) Slit Valve Door

(75) Inventors: Aaron Thrash, Gilroy, CA (US); Dean Tilles, Alameda, CA (US); Carole Trainer, Kulpsville, PA (US)

Correspondence Address: FLASTER/GREENBERG P.C.;8 PENN CENTER, 1628 JOHN F. KENNEDY BLVD., 15TH FLOOR, PHILADELPHIA, PA, 19103, US

(73) Assignee: Greene, Tweed of Delaware, Inc., Wilmington, DE (US)

(21) Appl. No.: 12/137,193

(22) Filed: Jun. 11, 2008

Related U.S. Application Data
(60) Provisional application No. 60/937,042, filed on Jun. 25, 2007.

(51) Int. Cl. F16K 3/02; F16K 51/02; H01L 21/67

(52) U.S. Cl. 251/170; 251/327; 118/733; 220/378

(57) ABSTRACT

The present invention provides a slit valve for sealing an opening in a chamber, wherein the slit valve includes a door having an interior and an exterior surface. A sealing member is disposed on the interior surface of the door near a periphery of the interior surface of the door, and a portion of the interior surface extends outwardly from the door and into the chamber so as to disrupt a flow of chemicals flowing towards the sealing member from within the chamber.

### CROSS REFERENCE TO RELATED APPLICATION

This application claims priority to U.S. Provisional Patent Application No. 60/937,042, filed Jun. 25, 2007, the contents of which are incorporated herein by reference.

### BACKGROUND OF THE INVENTION

Slit valve doors are commonly used with process reaction chambers in the semiconductor industry allowing for opening and closing a chamber when industry, processes such as chemical vapor deposition, plasma deposition, etching and the like are typically used. Such processes require the use of vacuum chambers and similar reactors in which harsh chemicals, high-energy plasmas and other corrosive materials are used creating very harsh environments.

Semiconductor process steps generally occur in an isolated environment in a series of interconnecting reaction and other chambers through which chips, chip wafer and other substrates can move or be moved robotically. This equipment is associated with various doors, gates, and/or valves. One such door includes a slit valve, which are made typically so as to have a resilient sealing ring that ensures adequate sealing of openings to a reaction chamber. Such sealing is important due to the nature of the reactants within the chamber. The seal functions to keep the chemical gases within the chamber and as a barrier to prevent outside impurities from contaminating the chamber; such contaminants may compromise the products prepared in the reaction chamber.

Problems can occur in many conventional slit valve designs when sealing rings wear and deteriorate over time due to exposure to harsh environments such as those associated with semiconductor high-energy plasma processing units. Wearing down of seals may result in process down-time (for seal replacement), as well as possible contamination of semiconductor products. Deterioration occurs even when the seals and fabricated of resistant materials such as perfluoroelastomers (FFKMs). When sufficient erosion or wear of the sealing material occurs, the slit valve can no longer function as intended causing process shut down for servicing and/or replacing the slit valve door.

FIG. 1 illustrates a partial cross-sectional view and general schematic representation of a conventional plasma processing chamber opening having a slit valve door used in the semiconductor industry. As shown in FIG. 1 (not drawn to scale), the flow of plasma gas 2 contacts the inwardly facing surface 6 of the slit valve door 4. The inwardly facing surface 6 is on the same general plane as the seal 8. The slit valve door 4 and inner surfaces of the reaction chamber 9 are typically made of the same material (generally metals, such as aluminum) and are generally made so as to be resistant to chemical attack. As such, the flow of plasma 2 contacts the flat inwardly facing surface 6 which diverts the plasma flow 2 to an area wherein the energy wavelength (necessary to maintain a plasma state) no longer exists. While the seal 8 is not in the line of sight from the direct plasma flow 2, the flow 2 will eventually pass through the gap 3 between the chamber and the internal surface 6 to contact the seal 8. Thus, the seal 8 is exposed to harmful gases and/or liquids.

One way to increase the life expectancy and performance of a slit valve door seal in the prior art has been to use barrier seals or shields, generally formed of a polymeric material. The barrier seal is typically located inwardly along the slit valve door surface near or adjacent to the sealing member so as to assist the sealing material by first contacting the exposure to harsh chemicals and/or plasma before the flow thereof can reach the sealing member. This technique has helped to increase seal life for typical slit valve doors used in plasma processing as much as ten times. However, the polymeric barrier is also susceptible to wear, such that over time it will still require replacement and/or repair in the same manner as the sealing member.

FIG. 1A illustrates a further, partial cross-sectional view of such a conventional prior art slit valve door currently used in the semiconductor industry. As shown in FIG. 1A (not drawn to scale), the flow of the plasma gas 2A contacts an inwardly facing surface 6 of the slit valve door 4A. Installed on the inward surface 6A is a T-shaped barrier material 7A that helps to divert the flow of plasma 2A after contact with the internal surface 6A from the seal 8A, as discussed above. The slit valve door 4A and the chamber (not shown) are typically made of the same material (such as aluminum) and are resistant to attack. The T-shaped material 7A is commonly a polymeric material such as, e.g., polytetrafluoroethylene (PTFE).

European Patent Application EP 1 028 278 A2 discloses a valve seal configuration for preventing gas flow between an opening and a sealing ring. The valve seal incorporates an insert barrier seal, made of a chemically resistant material such as PTFE, disposed to cover the opening of the chamber (where corrosive gases may be present). The barrier seal insert at least substantially covers the opening when the door is in a closed position. The location of the barrier seal insert is intended to isolate the sealing ring in a space between the valve seat, outer chamber wall, and the edge of the barrier seal insert so as to prevent any corrosive gases from coming in direct contact with the sealing member, and instead expose the barrier sealing member to such gases. However, this valve seal requires the use of a secondary sealing member and fasteners to attach the sealing member to a valve door, thus adding additional components to the valve door.

Thus, there is a continuing need in the art for improved valve designs that minimize exposure of valve sealing members to chemical and/or plasma attack and which maximize useful life in a simple economical design. Longer seal life reduces process costs by avoiding high expenses associated with unwanted process downtime, especially within the semiconductor processing industry.

### BRIEF SUMMARY OF THE INVENTION

The present invention is related to a slit valve door. In particular, the present invention is related to a modified slit valve door for use with chambers housing highly reactive chemicals, gaseous, and/or reactive species such as plasma and/or free radicals.

The invention includes a slit valve for sealing an opening of a chamber, the slit valve comprising a door having an interior and an exterior surface, wherein the interior surface has an outwardly extending portion; and a sealing member disposed near a periphery of the interior surface of the door, wherein the outwardly extending portion of the door is positioned so that upon installation of the door on a chamber, the outwardly extending portion extends at least partially into the chamber when the door is closed to disrupt a flow of chemicals flowing towards the sealing member from within the chamber.

Also included in the invention is a slit valve door for sealing an opening of a chamber, comprising an interior surface and an exterior surface, wherein the interior surface has an outwardly extending portion a sealing member disposed near a periphery of the interior surface of the door, wherein the outwardly extending portion of the door is positioned so that upon installation of the door in a closed position on a chamber, the outwardly extending portion extends at least partially into the chamber to disrupt a flow of chemicals flowing towards the sealing member from within the chamber.

The invention further includes a slit valve door for sealing an opening of a chamber, comprising an interior and an exterior surface, wherein the interior surface has an outwardly extending portion having a first raised portion and a second raised portion extending outwardly from the first raised portion; and a sealing member disposed near a periphery of the interior surface of the door spaced apart from the first raised portion to define a gap therebetween, wherein the outwardly extending portion of the door is positioned so that upon installation of the door in a closed position on a chamber having extending walls that define an opening, the outwardly extending portion extends at least partially into the chamber to disrupt a flow of chemicals flowing towards the sealing member from within the chamber, the walls cover the gap between the first raised portion and the sealing member, and the sealing member contacts the extending walls.

### BRIEF DESCRIPTION OF THE SEVERAL VIEWS OF THE DRAWINGS

The foregoing summary, as well as the following detailed description of the embodiments of the invention, will be better understood when read in conjunction with the appended drawings. It should be understood, however, that the invention is not limited to the precise arrangements and instrumentalities shown. In the drawings:

FIG. 1 is a cross-sectional view of a prior art, conventional slit valve door attached to a conventional chamber;

FIG. 1A is a cross-sectional view of a further prior art, conventional slit valve door;

FIG. 2 is a top plan view of the preferred embodiment of the slit valve door of the present invention;

FIG. 2A is a cross-sectional view of the embodiment of FIG. 2 taken along section 2A-2A of FIG. 2;

FIG. 2B is an enlarged view of area B of FIG. 2A;

FIG. 2C is an enlarged view of area B of FIG. 2A with the seal contacting the extending chamber walls of a plasma chamber in the installed position;

FIG. 2D is an enlarged view of an alternative seal configuration which may be used within the invention;

FIG. 2E is an enlarged view of a further alternative seal configuration which may be used within the invention;

FIG. 3 is a partial cross-sectional side view of a further embodiment of the slit valve door of the present invention installed on a plasma chamber;

FIG. 4 is a partial cross-sectional side view of a further embodiment of the slit valve door of the present invention installed on a plasma chamber; and

FIG. 5 is a partial cross-sectional view of a further embodiment of the slit valve door of the present invention installed on a plasma chamber.

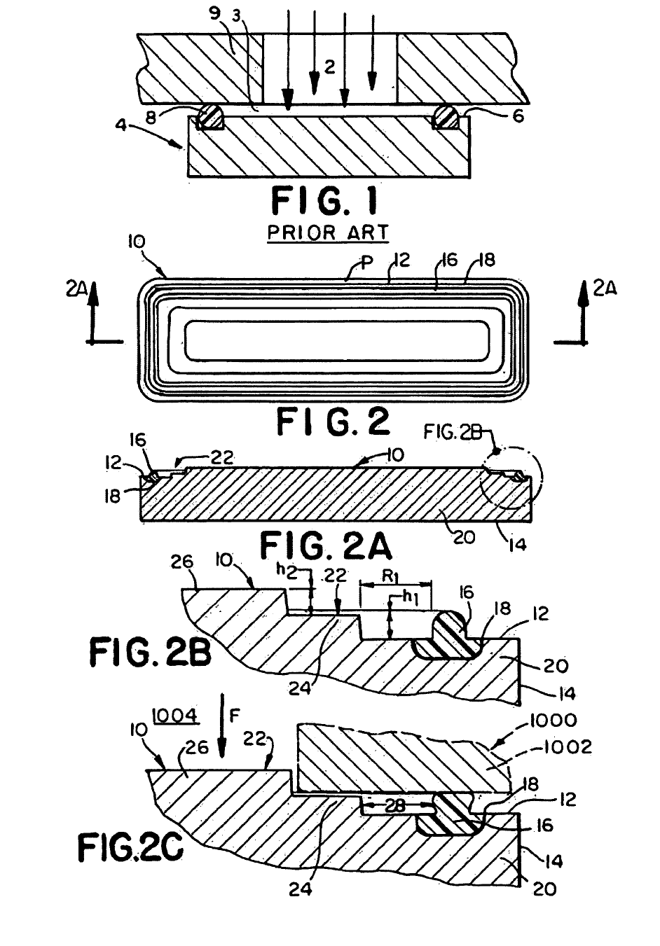

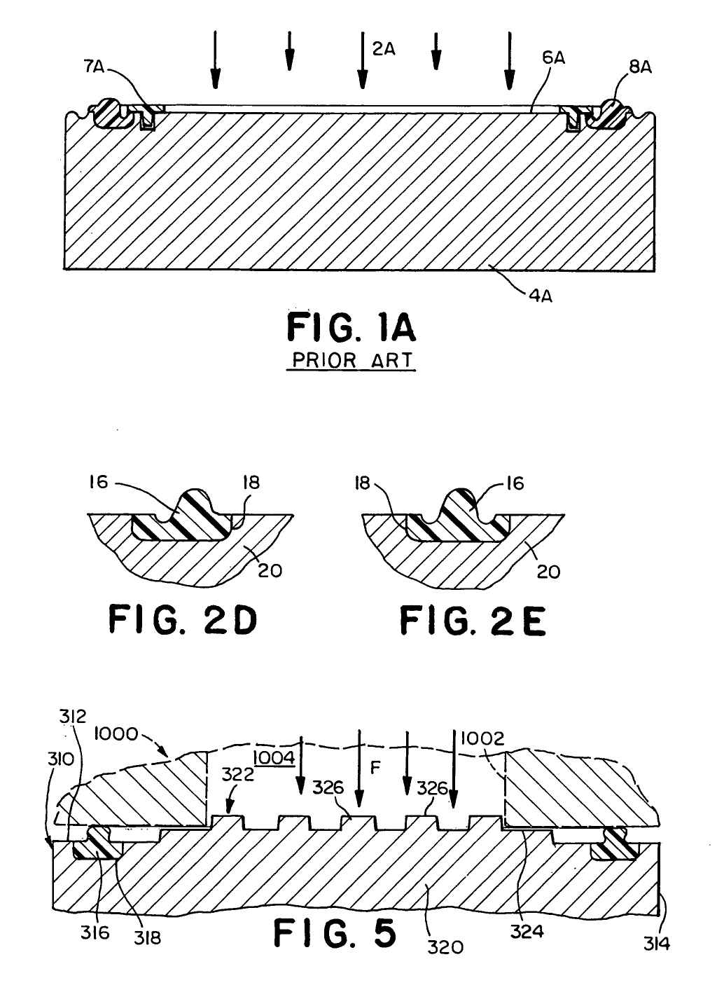

### DETAILED DESCRIPTION OF THE INVENTION

Referring to the drawings, wherein like numerals are used to designate like components throughout the several figures, there are shown embodiments of slit valves having slit valve doors according to the invention. In the drawings, words like “inwardly” and “outwardly” and “interior” and “exterior” related to directions in the drawings that are either towards or away from the surface of the door or are towards or away from the interior of a reaction chamber with which the slit valve door would be used, respectively. These words and words of similar import and/or providing direction are meant as guidelines for giving understanding to the drawings and should not be considered otherwise as limitations of the scope of the invention.

The embodiments of the slit valve doors shown in the drawings and as described herein are preferred embodiments only are should not be considered as limiting and may be used with various reaction chambers or other chambers which have therein harsh chemicals, including plasmas, etchants, feed materials and the like, which may contact and/or deteriorate seals positioned for use the slit valve doors described herein. Such chambers are typically used in the semiconductor processing industry to conduct for example, plasma etching or chemical vapor or plasma deposition, although the present invention can be applied to any similar type chambers for use in other industries, including pharmaceutical, chemical processing, fluid handling, nuclear, downhole, aerospace and other industries.

A preferred embodiment will now be described with respect to FIGS. 2, 2A, 2B and 2C that illustrate a slit valve door. The slit valve door, generally designated herein as 10, has a shape which is generally rectangular (but having somewhat rounded edges) as is typically encountered in semiconductor slit valve doors, but the door may be configured into any other shape suitable for use in a slit valve or related application for opening or closing a chamber (for example, the door may be generally square, elliptical, circular, oval, triangular, etc.).

The slit valve door 10 has an interior surface 12 and an exterior surface 14. The interior surface is situated so as to face the interior of a reaction or plasma chamber 1000 or the like, when the slit valve door 10 is installed in a closed position for use. The exterior surface 14 is situated so as to face away from the chamber 1000 when the slit valve door 10 is installed in a closed position for use.

The slit valve door 10 has a seal 16 that is positioned within a groove 14 arranged peripherally around the door. The seal 16 can include a variety of resilient materials as a base material including an elastomeric, polymeric and/or co-polymeric materials, and combinations and blends thereof. Preferably for high chemical and plasma resistance, the base material is a chemical- and plasma-resistant elastomer material such as a perfluoroelastomer (known in ASTM Standard Rubber Nomenclature as an FFKM elastomer). The base material may include an optional coating and can be filled or unfilled. Filler systems and coatings for such materials may be any which are already known in the art or to be developed for this purpose, as the composition of the seal is not critical to the present invention. Similarly, for less chemically resistant applications, standard fluoroelastomers (FKM elastomer) or PTFE, PTFE copolymers, EPDM, silicone, nitrile or natural rubber may be used. The slit valve door 10 can be made from any suitable material well known in the art, including preferably aluminum or stainless steel as is traditionally used for slit valve doors in semiconductor and highly chemically resistant applications.

The seal 16 is arranged, as shown in FIG. 2, so as to extend near a periphery P of the interior surface 12. The use of the term “near” as used herein can range generally from an order of magnitude of inches down to less than about a thousandth of an inch.

As best illustrated in FIGS. 2B and 2C, the slit valve door 10, having a door material 20, has an outwardly extending portion 22. When the door is considered in an uninstalled manner, the portion 22 extends outwardly from the interior surface 12 of the door in a transverse direction as measured across along the shorter direction of the door shown in FIGS. 2B and 2C. In this embodiment, the outwardly extended portion 22 has a first raised portion 24 and a second raised portion 26 that preferably extends further outwardly from the first raised portion and from the interior surface 12 of the door. Preferably, the slit valve door 10 is of one-piece construction to improve durability and thereby increase the life of the sealing member 16, based on the disruption of chemical flow F caused by the outwardly extending portion 22. The seal 16 may have a variety of cross-sectional configurations including, but not limited to, those illustrated in FIGS. 2B, 2D and 2E. The door material 20 is sculpted to define the outwardly extended portion 22 and the groove 18 so as obtain the proper shape for use as a slit valve door 10. In this embodiment, the door material 20 is any material that is known in the art or to be developed for use in slit valve or other chamber door applications, and preferably includes, at least partially or completely, a metal or metal alloy material, such as aluminum, anodized aluminum or stainless steel, and other similar materials.

FIG. 2B illustrates the relationship of the seal member 16 to the outwardly extending portion 22 of the slit valve door 10. FIG. 2C illustrates the same area showing the compressed configuration of the seal 16 upon installation of the door on a conventional plasma processing chamber 1000 along a wall 1002 which extends, and is configured so as to define, the chamber opening 1004 when the door is in a closed position against the chamber. Such chambers are known in the art and further details regarding the structure and operation of such chambers are not necessary for a complete understanding of the present invention. Exemplary chambers are shown in U.S. Pat. Nos. 7,062,347 and 7,056,831 incorporated in relevant part herein by reference. Typically, the walls of such a reaction chamber, as well as the slit valve door, are made of the same material, for example, aluminum or stainless steel. The present invention should be not considered as limited to plasma processing chambers, however, and it would be understood based on this disclosure that the doors may have other uses and may be placed on a variety of processing containment areas or other chambers.

The first raised portion 24 of the outwardly extending portion 22 is spaced apart from the seal 16 to define a gap 28 therebetween. The extending walls 1002 of the chamber 1000 are aligned to overlap the slit valve door 10 and to cover the gap 28 between the first raised portion 24 and the seal member 16 when the door is in the closed position, thereby extending towards the second raised portion 26, upon installation (and closure) of the slit valve door 10, against the chamber opening 1004 as shown in FIG. 2C.

The extending walls of the chamber 1002 contact the sealing member 16, but preferably do not contact the slit valve door 10 or door material 20 or other surfaces. This limited contact helps to eliminate production of particles or other material created by contact between the extending walls of the chamber 1002 and the door material 20. Production of such particles creates undesirable particulation and contamination of the plasma chamber 1000, which can cause contamination of the production of semiconductor chips within the chamber going through processing, resulting in loss of semiconductor chip yield. This can also be problematic if the doors are used in other chemical processing in which metals or other particles act as reaction contaminants. However, it will be recognized that contact, other than between the seal 16 and extending walls 1002, may also occur without departing from the spirit of the invention.

The second raised portion 26 extends further outwardly from the first raised portion 24 such that upon installation of the door in a closed position, the second raised portion extends further inwardly into the chamber opening 1004 defined by the extending walls of the chamber 1002. It is recognized, within the gap 28, that in a plasma process, no energy exists which supports the flow F of the plasma gas. Therefore, the door material 20 and the outwardly extending portion 22 act to create an area, the gap 28, in which corrosive plasma gas flow is reduced, resulting in minimal contact with the seal 16, thus, extending the life of the seal 16. The door material 20, and more specifically the extending portion 22, thereby acts to divert the attack of harsh chemicals that flow F from the main reaction area in the chamber opening 1004 towards the seal 16. Based on the design of the extended portion 22, any plasma gas must travel a tortuous path, including multiple directional turns around “corners”, to reach the seal 16. The “corner” configuration of the door, that helps prevent the flow F from getting in the gap 28, is made of aluminum (or related material as described herein) and therefore is not subject to attack like PTFE and other polymers, which while restraining, are still subject to erosion by ever increasing exposure to the harmful flow F.

In plasma processing, the seal 16 assists in creating a vacuum environment to preserve the conditions within the chamber walls 1002 when the door 10 is closed. Therefore, the greater the life of the seal 16, the less maintenance required of the plasma chamber 1000 resulting in reduced costs and greater efficiency.

In the preferred embodiment as illustrated in FIG. 2B, the first raised portion 24 is at an increased height (h₁) (measured in the transverse direction of the door as shown) of about 0.01 mm to about 5 mm, preferably about 2 mm, in the direction of the chamber opening 1004 when the slit valve door 10 is closed. The gap 28, which defines the distance from the first raised portion 24 to the seal 16, is preferably a distance (R₁) (measured longitudinally along the door) of about 0.01 mm to about 25 mm. The second raised portion 26 has an increased height (h₂) (measured in the transverse direction of the door) of about 0.01 mm to about 25 mm, preferably about 2 mm, above the first raised portion 24. Though these proportions may be optimal, the spatial relationship described herein should not be considered limiting, as it will be understood based on this disclosure that the distance from the seal member 16 to the extending portion 22, and the size and shape of the extending portion 22 may be varied within the scope of the invention. Alternatively, the outwardly extending portion 22 of the door material 20 can include a variety of configurations that disrupt or redirect the flow F of plasma gas away from the seal member 16.

FIG. 3 is a cross-sectional view of another embodiment of the present invention illustrating the compressed configuration of the sealing member 116 upon installation in a closed position against a conventional plasma-processing chamber 1000 along extending walls 1002 defining an opening 1004. The slit valve door 110, having an interior surface 112 with a seal member 116, includes a door material 120 with an outwardly extending portion 122. The extending portion 122 includes a first raised portion 124 and a second raised portion 126, wherein the second raised portion 126 is configured to have layers of different lengths as measured longitudinally along each layer to disrupt the plasma gas flow F.

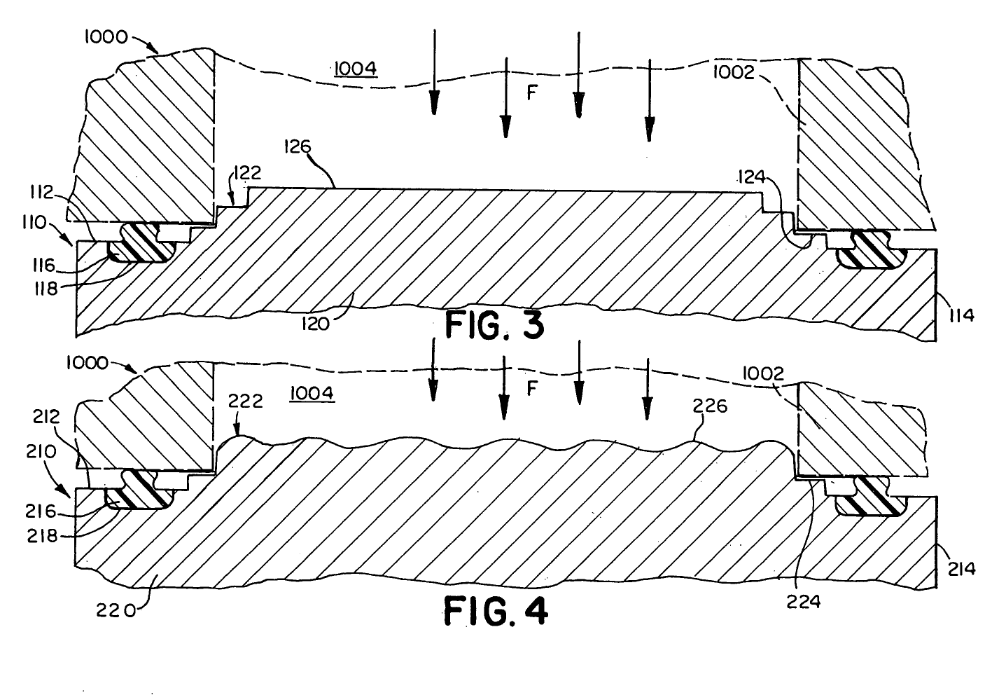

FIG. 4 is a cross-sectional view of a further embodiment of the present invention illustrating a compressed configuration of a seal 216 upon installation in a closed position on a conventional plasma-processing chamber 1000 along extending walls 1002 defining an opening 1004. The slit valve door 210, having an interior surface 212 with a seal member 216, includes a door material 220 with an outwardly extending portion 222. The extending portion 222 includes a first raised portion 224 and a second raised portion 226, wherein the second raised portion 226 has a contoured configuration on its upper surface to assist in disrupting the plasma gas flow F.

FIG. 5 is a cross-sectional view of another embodiment of the present invention illustrating a seal 316 in compressed configuration upon installation in a closed position on a conventional plasma-processing chamber 1000 along an extending wall 1002 defining an opening 1004. The slit valve door 310, having an interior surface 312 with a seal member 316, includes a door material 320 with an extending portion 322. The extending portion 322 includes a first raised portion 324 and a second raised portion 326, wherein the second raised portion 326 is configured as a series of projections to assist in disrupting the plasma gas flow F. It will be understood by those skilled in the art based on this disclosure that the projections 326 can be of various shapes and sizes and remain within the spirit of this invention.

It will be appreciated by those skilled in the art that changes can be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A slit valve for sealing an opening of a chamber, the slit valve comprising:
a door having an interior and an exterior surface, wherein the interior surface has an outwardly extending portion; and
a sealing member disposed near a periphery of the interior surface of the door, wherein the outwardly extending portion of the door is positioned so that upon installation of the door on a chamber, the outwardly extending portion extends at least partially into the chamber when the door is closed to disrupt a flow of chemicals flowing towards the sealing member from within the chamber.

2. The slit valve of claim 1, wherein the outwardly extending portion of the door comprises a first raised portion and a second raised portion.

3. The slit valve of claim 2, wherein the first raised portion is spaced apart from the sealing member to define a gap therebetween.

4. The slit valve of claim 3, wherein the door is configured such that upon installation on a chamber having extending walls in a closed position, the walls will cover the gap between the first raised portion and the sealing member, and the sealing member will contact the extending walls.

5. The slit valve of claim 4, wherein the second raised portion extends outwardly from the first raised portion so that when the door is installed on a chamber in a closed position the second raised portion extends into the chamber.

6. The slit valve of claim 5, wherein the second raised portion further comprises a series of projections so that when the door is installed on a chamber in a closed position, the projections extend into the chamber.

7. The slit valve of claim 5, wherein the second raised portion has multiple layers so that when the door is installed on a chamber in a closed position, the layers are directed inwardly into the chamber.

8. The slit valve of claim 7, wherein the multiple layers are each of a different length measured longitudinally along each layer.

9. The slit valve of claim 5, wherein the second raised portion has contoured ends so that when the door is installed on a chamber in a closed position, the contoured ends are directed into the chamber.

10. The slit valve of claim 1, wherein the sealing member comprises a perfluoroelastomer.

11. The slit valve of claim 1, wherein the door material comprises a metal or metal alloy.

12. The slit valve of claim 11, wherein the door material is aluminum.

13. A slit valve door for sealing an opening of a chamber, comprising
an interior surface and an exterior surface, wherein the interior surface has an outwardly extending portion; and
a sealing member disposed near a periphery of the interior surface of the door,
wherein the outwardly extending portion of the door is positioned so that upon installation of the door in a closed position on a chamber, the outwardly extending portion extends at least partially into the chamber to disrupt a flow of chemicals flowing towards the sealing member from within the chamber.

14. The slit valve door of claim 13, wherein the outwardly extending portion of the door comprises a first raised portion and a second raised portion.

15. The slit valve door of claim 14, wherein the first raised portion is spaced apart from the sealing member to define a gap therebetween.

16. The slit valve door of claim 15, wherein the door is configured such that upon installation on a chamber having extending walls in a closed position, the walls will cover the gap between the first raised portion and the sealing member, and the sealing member will contact the extending walls.

17. The slit valve door of claim 16, wherein the second raised portion extends outwardly from the first raised portion on the door so that when the door is installed on a chamber in a closed position the second raised portion extends into the chamber.

18. A slit valve door for sealing an opening of a chamber, comprising
an interior and an exterior surface, wherein the interior surface has an outwardly extending portion having a first raised portion and a second raised portion extending outwardly from the first raised portion; and
a sealing member disposed near a periphery of the interior surface of the door spaced apart from the first raised portion to define a gap therebetween,
wherein the outwardly extending portion of the door is positioned so that upon installation of the door in a closed position on a chamber having extending walls that define an opening, the outwardly extending portion extends at least partially into the chamber to disrupt a flow of chemicals flowing towards the sealing member from within the chamber, the walls cover the gap between the first raised portion and the sealing member, and the sealing member contacts the extending walls.

19. The slit valve door of claim 18, wherein the second raised portion has multiple layers so that when the door is installed on a chamber in a closed position, the layers are directed inwardly into the chamber.

20. The slit valve door of claim 19, wherein the multiple layers are each of a different length measured longitudinally along each layer.

21. The slit valve door of claim 18, wherein the second raised portion has contoured ends so that when the door is installed on a chamber in a closed position, the contoured ends are directed into the chamber.
